(19) United States
(12) Patent Application Publication
(10) Pub. No.: US 2008/0157134 A1
(43) Pub. Date: Jul. 3, 2008

(54) CMOS IMAGE SENSOR AND FABRICATING METHOD THEREOF

(75) Inventor: Chang Eun LEE, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/948,815

(22) Filed: Nov. 30, 2007

(30) Foreign Application Priority Data
Dec. 29, 2006 (KR) 10-2006-0137556

(51) Int. Cl. H01L 27/146; H01L 31/0232

(52) U.S. Cl. 257/290; 438/69; 257/E27.13; 257/E31.127

(57) ABSTRACT

A CMOS image sensor and method the same are disclosed. The method comprises forming an insulating interlayer including a plurality of photodiodes on a semiconductor substrate, forming a plurality of metal lines within the insulating interlayer, sequentially forming an oxide layer and a passivation layer on the insulating interlayer, forming a TEOS layer on the passivation layer, forming a planarization layer on a portion of the TEOS layer, and forming a microlens on the planarization layer.

### BACKGROUND OF THE INVENTION

This application claims the benefit of the Korean Patent Application No. 10-2006-0137556, filed on Dec. 29, 2006, which is hereby incorporated by reference in its entirety.

### BACKGROUND OF THE INVENTION

1. Field of the Invention

The present invention relates to a CMOS image sensor and method of fabricating the same. More particularly, the present invention relates to a method for preventing a step phenomenon from being formed in the CMOS image sensor.

2. Discussion of the Related Art

An image sensor is a device which is capable of converting an optical image to an electric signal. Within each image sensor, a charge coupled device (CCD) which includes a number of MOS (metal-oxide-silicon) capacitors provided close to each other. Within each capacitor, carriers are stored until they are subsequently transported.

One type of image sensor is a CMOS image sensor, which is an image sensor that adopts a switching system including MOS transistors a number of pixels depending on the type of CMOS technology. The CMOS image sensors use a control circuit and a signal processing circuit as a peripheral circuit in order to sequentially detect outputs using the MOS transistors.

FIG. 1 and FIG. 2 are diagrams illustrating the configuration of a CMOS image sensor known in the art. Typically, the CMOS image sensor of the prior art consists of a plurality of pixels intensively aligned into rows and columns on a semiconductor epitaxial layer. As shown in FIG. 1, the CMOS image sensor consists of a photodiode 110 capable of generating photoelectrons by sensing incoming light, a floating diffusion region 120 capable of delivering charges generated from the photodiode 110, and a transfer transistor 122 disposed between the photodiode 110 and the floating diffusion region 120 which is capable of transferring the charges generated from the photodiode 110 to the floating diffusion region 120.

In association with FIG. 1, FIG. 2 is a diagram illustrating the electrical configuration of a CMOS image sensor. Firstly, when the reset transistor 124 is turned on, the electric potential of an output floating diffusion node becomes VDD so as to detect a reference value. Then, light is received by a photodiode 110 acting as a light receiving unit, and an electron hole pair (EHP) is proportionally generated. Next, electron hole pair, acting as signal charges generated from the photodiode 110 vary the potential at a source node of a transfer transistor 122 in proportion to the quantity of the signal charges.

Then, if the transfer transistor 122 is turned on, accumulated signal charges are transferred to a floating diffusion region. Thus, the potential of an output floating diffusion node varies in proportion to the charge quantity of the transferred signal. At the same time, the gate bias of a select transistor 126 varies. This results in the variation of the source potential of the select transistor 126.

As the source potential of the select transistor 126 varies, an access transistor 128 is turned on. When the access transistor 128 is turned on, data is read out toward the column. Then, if the reset transistor 124 is turned on, the potential of an output floating diffusion node is returned to VDD, and the process may be repeated.

In some embodiments, a color filter array of colors is provided over photodiodes in order to receive red, green and blue signals, respectively, and a microlens is provided on the surface of the light receiving unit to increase the amount of light received by the light receiving unit.

In a image sensor where the photodiodes are vertically aligned, however, the red, green and blue signals absorbed in the silicon have different wavelength depths, so the photodiodes may be located to receive the different wavelength depths, removing the need for a color filter array. Instead, a microlens is provided directly on a passivation nitride layer, and each channel signal is transferred to an image processing circuit provided outside a light receiving unit via a plurality of metal lines. The channel signals are then recombined into a single image via signal processing.

In addition to the removal of the color filter array, technological developments, including 0.18 μM and 0.13 μm technologies, have further reduced the size of pixel.

FIG. 3 is a cross-sectional diagram illustrating a method of fabricating a CMOS image sensor according to the prior art. As shown in FIG. 3, a first epitaxial layer 310 is grown on a semiconductor device 300 and a red photodiode 312 is formed on the first epitaxial layer 310. A second epitaxial layer 320 is grown on the first epitaxial layer 310 and red photodiode 312 and a green photodiode 322 is then formed on the second epitaxial layer 320.

A third epitaxial layer 330 is grown on the second epitaxial layer 320 and green photodiode 322, and a blue photodiode 332 and a trench for inter-field isolation are formed on the third epitaxial layer 330, followed by an STI (shallow trench isolation) layer 334 to fill the trench.

An insulating interlayer 340 is then formed on the third epitaxial layer 330, and a via hole 342 is formed by selectively etching the insulating interlayer 340. A metal layer (not shown) is then formed on the insulating interlayer 340, and a metal line (not shown) and a metal pad 350 are then formed by patterning the metal layer.

A first insulating layer 360 of oxide and a second insulating layer 370 of nitride are sequentially stacked on the metal pad 350 and insulating interlayer 340 to protect the device from moisture and/or physical shock. The second insulating layer 370 is then selectively etched to expose the metal pad 350, and then an annealing process is performed.

Subsequently, a microlens 380 is formed on the second insulating layer 370. In this case, the microlens 380 is formed of photoresist of polymer. Since the metal pad 350 may corrode by being exposed to a development solution in the course of manufacturing after patterning the microlens 380, a very thin TEOS layer is deposited on the whole substrate 300 including the metal pad 350 prior to forming the microlens 380. The TEOS layer is then removed.

However, in removing the TEOS layer after the formation of the microlens 380, a step phenomenon, as shown in FIG. 4, may occur due to the etch selectivity difference between the TEOS layer and the lower nitride layer. Unfortunately, the step phenomenon causes the light received by a pixel light receiving unit to diffuse, degrading the image quality.

### SUMMARY OF THE INVENTION

Accordingly, the present invention is directed to a CMOS image sensor and method of fabricating the same that substantially obviates one or more problems, limitations, or disadvantages of the related art.

More specifically, an object of the present invention is to provide a CMOS image sensor and method of fabricating the same, wherein the step phenomenon generated by a difference in etch selectivity between a TEOS layer and a lower nitride layer can be prevented.

To achieve these objects and other advantages and in accordance with the purpose of the invention, one aspect of the invention is a CMOS image sensor comprising an insulating interlayer on a semiconductor substrate including a plurality of photodiodes, a plurality of metal lines within the insulating interlayer, an oxide layer on the insulating interlayer, a passivation layer on the oxide layer, a TEOS layer on one side of the passivation layer, a planarization layer on the TEOS layer, and a plurality of microlenses on the planarization layer.

Another aspect of the present invention is a method of fabricating a CMOS image sensor comprising forming an insulating interlayer on a semiconductor substrate including a plurality of photodiodes, forming a plurality of metal lines within the insulating interlayer, sequentially forming an oxide layer and a passivation layer on the insulating interlayer, forming a TEOS layer on the passivation layer, forming a planarization layer on one side of the TEOS layer, and forming a microlens on the planarization layer.

Additional advantages, objects, and features of the invention will be set forth in part in the description which follows and in part will become apparent to those having ordinary skill in the art upon examination of the following or may be learned from practice of the invention. The objectives and other advantages of the invention may be realized using the structure particularly pointed out in the written description, claims, and appended drawings.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings are included to provide a further understanding of the invention and are incorporated in and constitute a part of this application. The drawings illustrate embodiment(s) of the invention and together with the description serve to explain the principle of the invention. In the drawings:

FIGS. 1 and 2 are diagrams illustrating the electronic configuration of a general CMOS image sensor;

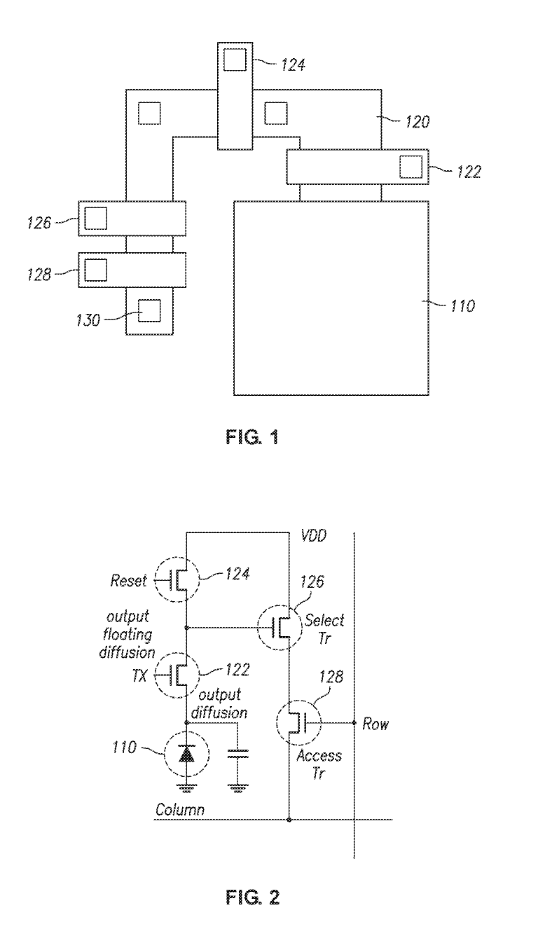

FIG. 3 is a cross-sectional diagram illustrating a method of fabricating a CMOS image sensor according to a related art;

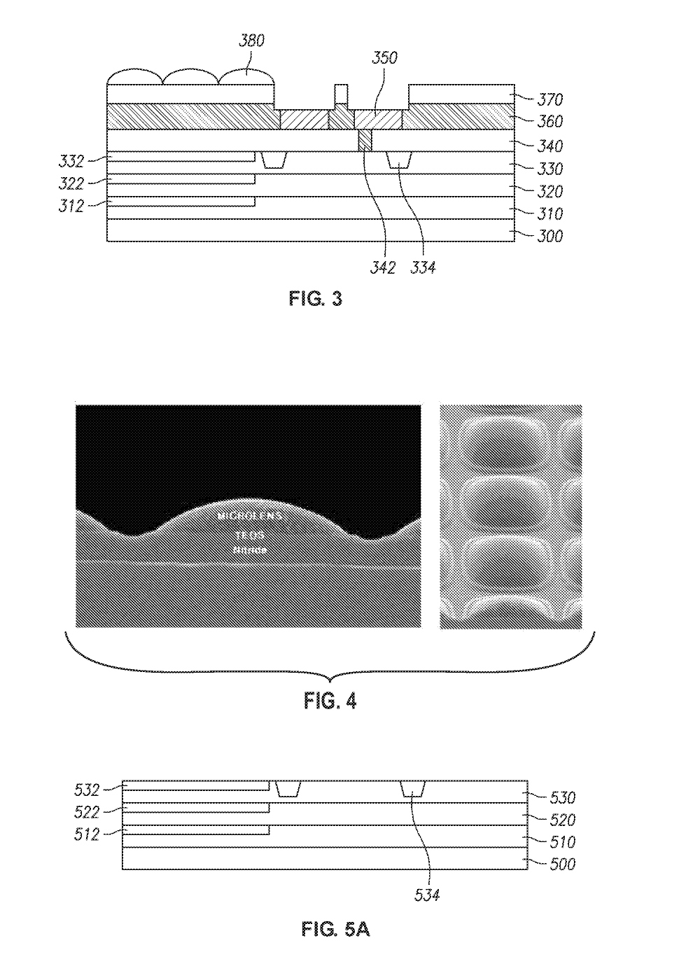

FIG. 4 is a picture of a step phenomenon generated by a difference in etch selectivity between a TEOS layer and a lower nitride layer; and

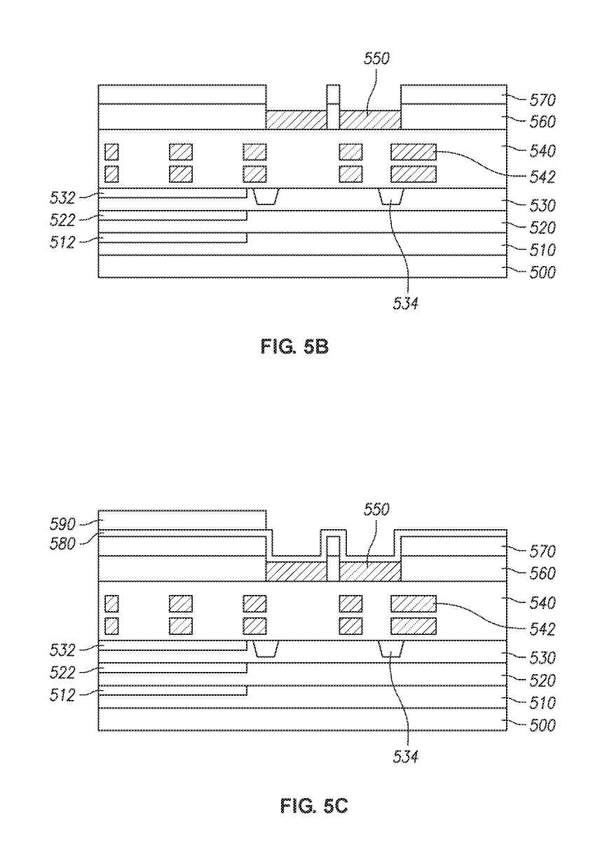

FIGS. 5A to 5E are cross-sectional diagrams illustrating a method of fabricating a CMOS image sensor according to one embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

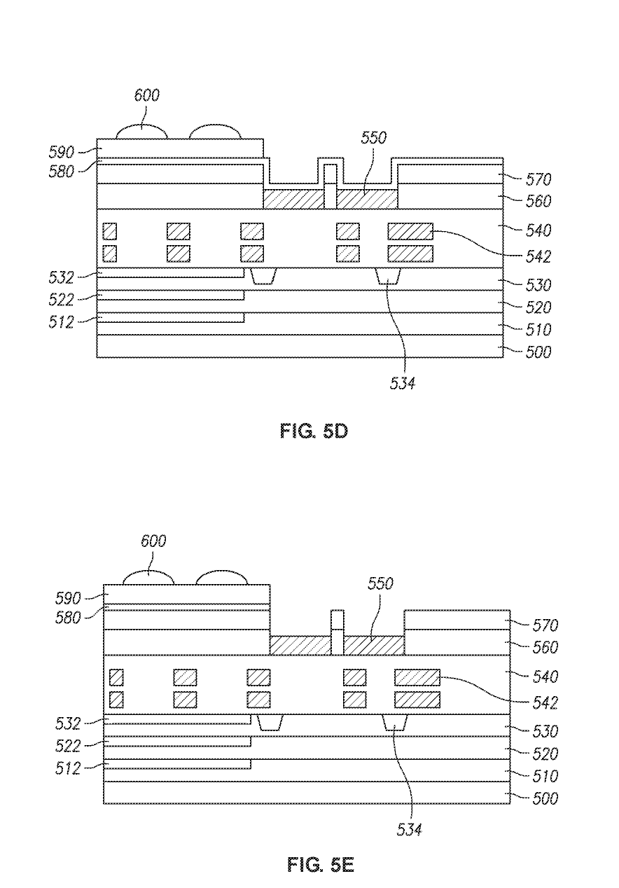

FIGS. 5A to 5E are cross-sectional diagrams illustrating a method of fabricating a CMOS image sensor according to one embodiment of the present invention.

First, as shown in FIG. 5A, a first epitaxial layer 510 is grown on a semiconductor device 500. Then, a red photodiode 512 is formed on the first epitaxial layer 510. A second epitaxial layer 520 is grown on the first epitaxial layer 510 and red photodiode 512 and a green photodiode 522 is then formed on the second epitaxial layer 520.

A third epitaxial layer 530 is grown on the second epitaxial layer 520 and green photodiode 522. A blue photodiode 532 and a trench for inter-field isolation are formed on the third epitaxial layer 530. An STI (shallow trench isolation) layer 534 is then formed to fill the trench, and an insulating interlayer 540 is stacked on the third epitaxial layer 530.

Then, as shown in FIG. 5B, a first metal layer (not shown) is formed on the insulating interlayer 540 and then patterned in order to form a metal line 542. In this case, the step of forming the insulating interlayer 540 and the metal line 542 is repeated several times to form a plurality of metal lines 542. Subsequently, a second metal layer (not shown) is formed on the insulating interlayer 540 and then patterned in order to form a metal pad 550.

An oxide layer 560 and a passivation layer 570 are sequentially deposited on the semiconductor substrate 500 and metal pad 550 in order to protect the device from moisture and/or physical shock. The oxide layer 560 and passivation layer 570 are then patterned in order to expose a surface of the metal pad 550. In this case, the passivation layer 570 includes a nitride layer.

A TEOS layer 580 and a planarization layer 590 are sequentially deposited on the whole semiconductor substrate including the oxide and passivation layers 560 and 570. A portion of the planarization layer 590 is removed except in the area where a microlens 600 will be formed, as shown in FIG. 5C. In this case, the planarization layer is formed of polymer series material so as to prevent the step phenomenon.

A photoresist is coated on the whole substrate 500 including the planarization layer 590. Exposure and development is selectively performed in order to form a microlens pattern (not shown). Annealing is then performed to form a microlens 600 having a prescribed curvature.

Subsequently, the TEOS layer 580 is removed except in the area under the microlens 600. Then, as shown in FIG. 5W, metal pad 550 is opened.

The present invention provides the following effects or advantages. Firstly, the present invention inserts a planarization layer of polymer beneath the microlens, thereby preventing the step phenomenon generated from a difference in etch selectivity between the TEOS layer and a lower nitride layer. Secondly, the present invention achieves planarization on a light receiving unit, thereby providing a high-quality microlens.

It will be apparent to those skilled in the art that various modifications and variations can be made in the present invention without departing from the spirit or scope of the inventions. Thus, it is intended that the present invention covers the modifications and variations of this invention that come within the scope of the appended claims and their equivalents.

What is claimed is:

1. A CMOS image sensor comprising:
an insulating interlayer formed on a semiconductor substrate, the insulating interlayer including a plurality of photodiodes;
a plurality of metal lines formed within the insulating interlayer;
an oxide layer formed on the insulating interlayer;
a passivation layer formed on the oxide layer;
a TEOS layer formed on a portion of the passivation layer;
a planarization layer formed on the TEOS layer; and
a plurality of microlenses formed on the planarization layer.

2. The CMOS image sensor of claim 1, wherein the planarization layer is formed of polymer series material.

3. The CMOS image sensor of claim 1, wherein the passivation layer includes a nitride layer.

4. A method of fabricating a CMOS image sensor, comprising:
forming an insulating interlayer including a plurality of photodiodes on a semiconductor substrate;
forming a plurality of metal lines within the insulating interlayer;
sequentially forming an oxide layer and a passivation layer on the insulating interlayer;
forming a TEOS layer on the passivation layer;
forming a planarization layer on a portion of the TEOS layer; and
forming a microlens on the planarization layer.

5. The method of claim 4, wherein the planarization layer is formed of polymer series material.

6. The method of claim 4, wherein forming the planarization layer on a portion of the TEOS layer comprises:
depositing the planarization layer on the TEOS layer; and
removing the planarization layer from a portion of the TEOS layer except in an area beneath where the microlens will be formed.

7. The method of claim 4, further comprising removing the TEOS layer except in an area beneath the microlens.

8. The method of claim 4, further comprising:
forming a metal pad on the insulating interlayer by forming a metal layer on the insulating interlayer and forming the metal layer into a pattern.

9. The method of claim 4, wherein the passivation layer comprises a nitride layer.

10. A method of fabricating a CMOS image sensor, comprising:
forming an insulating interlayer including a plurality of photodiodes on a semiconductor substrate;
forming a plurality of metal lines within the insulating interlayer;
sequentially forming an oxide layer and a passivation layer on the insulating interlayer;
forming a TEOS layer on the passivation layer;
forming a planarization layer on a portion of the TEOS layer where a microlens will be formed;
forming the microlens on the planarization layer; and
removing the TEOS layer except in an area beneath the microlens.

11. The method of claim 10, wherein the planarization layer is formed of polymer series material.

12. The method of claim 10, wherein forming the planarization layer on a portion of the TEOS layer comprises:
depositing the planarization layer on the TEOS layer; and
removing the planarization layer from a portion of the TEOS layer except in an area beneath where the microlens will be formed.

13. The method of claim 10, further comprising:
forming a metal pad on the insulating interlayer by forming a metal layer on the insulating interlayer and forming the metal layer into a pattern.

14. The method of claim 10, wherein the passivation layer comprises a nitride layer.
